(19) United States
(12) Patent Application Publication
(10) Pub. No.: US 2015/0109431 A1
(43) Pub. Date: Apr. 23, 2015

(54) Systems and Methods for Material Texture Analysis

(71) Applicant: EDAX, MATERIALS ANALYSIS DIVISION OF AMETEK INC., MAHWAH, NJ (US)

(72) Inventors: Stuart I. Wright, Orem, UT (US); Matthew M. Nowell, Riverton, UT (US); Peter A. de Kloe, Dongen (NL); Travis Michael Rampton, West Milford, NJ (US); Patrick Paul Camus, Pen Argyl, PA (US)

(21) Appl. No.: 14/299,063

(22) Filed: Jun. 9, 2014

Related U.S. Application Data
(60) Provisional application No. 61/940,871, filed on Feb. 18, 2014.
(60) Provisional application No. 61/892,677, filed on Oct. 18, 2013.

(51) Int. Cl. G01N 23/203; G06K 9/62; G06K 9/46; H01J 37/244; H01J 37/28

(52) U.S. Cl. CPC G01N 23/203; H01J 37/244; H01J 37/28; G06K 9/4604; G06K 9/6202; H01J 2237/24571; H01J 2237/221
USPC 348/79

(57) ABSTRACT

The present inventions are related to systems and methods for determining characteristics of a material. The characteristics may include, but are not limited to, crystallographic texture.

### CROSS REFERENCE TO RELATED APPLICATIONS

The present application claims priority to (is a non-provisional of) Provisional U.S. Pat. App. No. 61/940,871 entitled “SYSTEMS AND METHODS FOR MATERIAL ANALYSIS” and filed by Wright on Feb. 18, 2014; and Provisional U.S. Pat. App. No. 61/892,677 entitled “VISUAL FORWARD SCATTER DETECTOR” and filed by Wright on Oct. 18, 2013. The entirety of the aforementioned references is incorporated herein by reference for all purposes.

### BACKGROUND OF THE INVENTION

The present inventions are related to systems and methods for determining characteristics of a material. The characteristics may include, but are not limited to, crystallographic texture.

Scanning Electron Microscopes (SEM) have been used to investigate characteristics of samples. Use of SEMs to investigate the crystallographic and chemical composition characteristics of a sample suffers from one or more limitations. For example, scanning the surface of a material may be time consuming and costly, and does not provide the desired information.

Hence, for at least the aforementioned reasons, there exists a need in the art for advanced systems and methods for investigating samples.

### BRIEF SUMMARY OF THE INVENTION

The present inventions are related to systems and methods for determining characteristics of a material. The characteristics may include, but are not limited to, crystallographic texture.

Various embodiments of the present invention provide systems for determining a crystallographic orientation of a material sample. The systems include: a data detector system and a microprocessor. The detector system is operable to generate an image corresponding to a location on a surface of a material sample. The microprocessor operable to execute instructions to: access a data set corresponding to the image; using the data set to map locations in the image exhibiting an intensity greater than a threshold intensity to yield an image constellation; compare the image constellation with an expected constellation to yield a match indication; and identify the location on the surface of the material as having a crystallographic orientation corresponding to the expected constellation based upon the match indication.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a material investigation system in accordance with various embodiments of the present invention;

FIG. 2 is a flow diagram showing a method in accordance with some embodiments of the present for investigating a sample using a binning approach;

FIGS. 3a-3c graphically shows composite images of a region of a material surface represented using the full pixel array (FIG. 3b) and then with super pixels (FIG. 3c) in accordance with various embodiments of the present invention;

FIG. 4 is a flow diagram showing a method in accordance with some embodiments of the present for performing texture analysis of a material sample in accordance with various embodiments of the present invention;

FIG. 5a graphically represents the crystal orientations within a material without a texture that may be used in performing texture analysis in accordance with some embodiments of the present invention;

FIG. 5b graphically represents the crystal orientations within a material with a texture that may be used in performing texture analysis in accordance with some embodiments of the present invention

FIG. 5c shows an EBSD pattern from a crystalline material with 3 points of interest highlighted.

FIG. 5d shows a binned schematic of 5c as a 3×3 array of super pixels with the pixels highlighted in correspondence with the 3 points of interest in FIG. 5c; and

FIG. 6 is a flow diagram showing another method in accordance with other embodiments of the present for performing texture analysis of a material sample in accordance with various embodiments of the present invention.

### DETAILED DESCRIPTION OF THE INVENTION

The present inventions are related to systems and methods for determining characteristics of a material. The characteristics may include, but are not limited to, crystallographic texture.

Various embodiments of the present invention provide systems for determining a crystallographic orientation of a material sample. The systems include: a data detector system and a microprocessor. The detector system is operable to generate an image corresponding to a location on a surface of a material sample. The microprocessor operable to execute instructions to: access a data set corresponding to the image; using the data set to map locations in the image exhibiting an intensity greater than a threshold intensity to yield an image constellation; compare the image constellation with an expected constellation to yield a match indication; and identify the location on the surface of the material as having a crystallographic orientation corresponding to the expected constellation based upon the match indication.

In some instances of the aforementioned embodiments, the microprocessor is further operable to execute instructions to: receive pixel data from the detector circuit; and combine subsets of the pixel data to yield a set of super pixels. The data set corresponding to the image includes the set of super pixels. In particular instances of the aforementioned embodiments, each of the pixel data from the detector circuit is an intensity value corresponding to a sub-location within the image. Each of the super pixels is a value corresponding to an average of intensity values for each of the pixel data from the detector circuit included in the subset of the pixel data corresponding to a respective one of the super pixels. In various instances, the size of the subset of pixel data combined to yield a respective super pixel is user programmable. In some cases, the image constellation is a map of the super pixels in the image that exceed the threshold intensity. In one particular case, the threshold intensity is user programmable.

In some instances of the aforementioned embodiments, the location on a surface of the material sample is a first location on the surface of the material sample, the image is a first image, the data set corresponding to the image is a first data set corresponding to the first image, the image constellation is a first image constellation, the match indication is a first match indication, the detector system is further operable to generate a second image corresponding to a second location on the surface of a material sample. In such instances, the microprocessor may be further operable to execute instructions to: access a second data set corresponding to the second image; using the second data set to map locations in the second image exhibiting an intensity greater than the threshold intensity to yield a second image constellation; compare the second image constellation with the expected constellation to yield a second match indication; and identify the second location on the surface of the material as having a crystallographic orientation corresponding to the expected constellation based upon the second match indication. In some cases, the pixel data is a first pixel data, the set of super pixels is a first set of super pixels, the pixel data is a first pixel data, and the microprocessor is further operable to execute instructions to: receive a second pixel data from the detector circuit; and combine subsets of the second pixel data to yield a second set of super pixels. The second data set corresponding to the second image includes the second set of super pixels. In some cases, the microprocessor is further operable to execute instructions to calculate a fraction of locations on the surface of the material sample that match the expected constellation.

Other embodiments of the present invention provide methods for characterizing a material. The methods include: receiving an image corresponding to a location on a surface of a material sample; accessing a data set corresponding to the image; using the data set and a microprocessor to map locations in the image exhibiting an intensity greater than a threshold intensity to yield an image constellation; comparing the image constellation with an expected constellation to yield a match indication; and identifying the location on the surface of the material as having a crystallographic orientation corresponding to the expected constellation based upon the match indication.

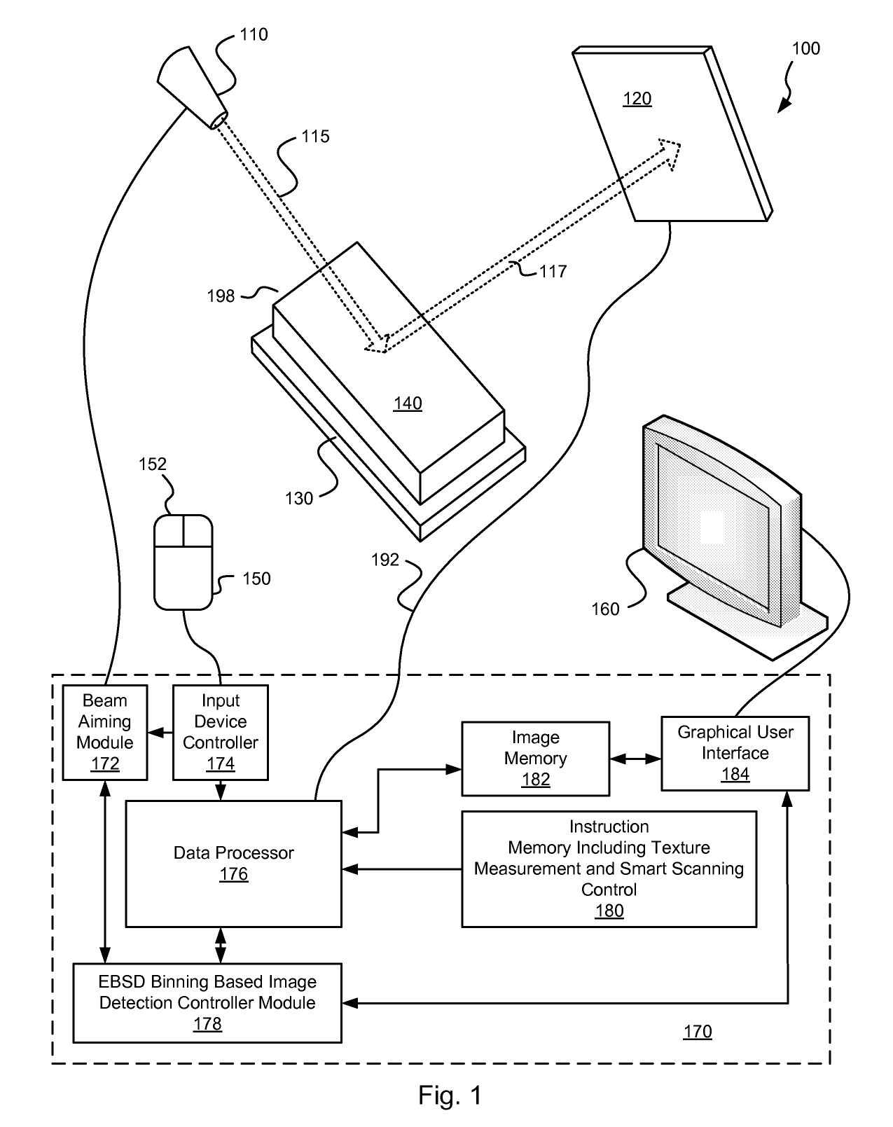

Turning to FIG. 1, a material investigation system 100 is shown in accordance with various embodiments of the present invention. Material investigation system 100 includes a radiation source 110 that in this case emits an electron beam 115 toward a material sample 140 that is placed on a carrier 130. In one particular embodiment of the present invention, radiation source 110 is part of a scanning electron microscope. Electron beam 115 scatters off of the material sample as a scattered radiation 117 toward a detector 120. The scattered radiation may include a number of elements including, but not limited to, backscatter diffracted electrons, secondary electrons, auger electrons, cathodoluminescence, and characteristic X-rays. If we focus on backscatter diffracted electrons within the scattered radiation 117 then if the correct sensor 120 is used an electron back scatter diffraction (EBSD) pattern is created on a surface of detector 120 that is transferred to a data processor 176. In some embodiments of the present invention, detector 120 includes a phosphor based sensor that glows at locations impacted by elements of diffracted scattered radiation 117. An array of charged coupled devices (CCD) is disposed in relation to the phosphor based sensor to convert the light emitted by the phosphor based sensor into an image comprising an array of pixel data. This pixel data is transferred to data processor 176 via a signal data 192. Of note, detector 120 may be replaced by a number of different sensors as are known in the art including, but not limited to, a forward scatter detector. In some cases, detector 120 may be a combination of one or more sensors. Based upon the disclosure provided herein, one of ordinary skill in the art will recognize a variety of sensors or combinations of sensors that may be utilized in accordance with different embodiments of the present invention

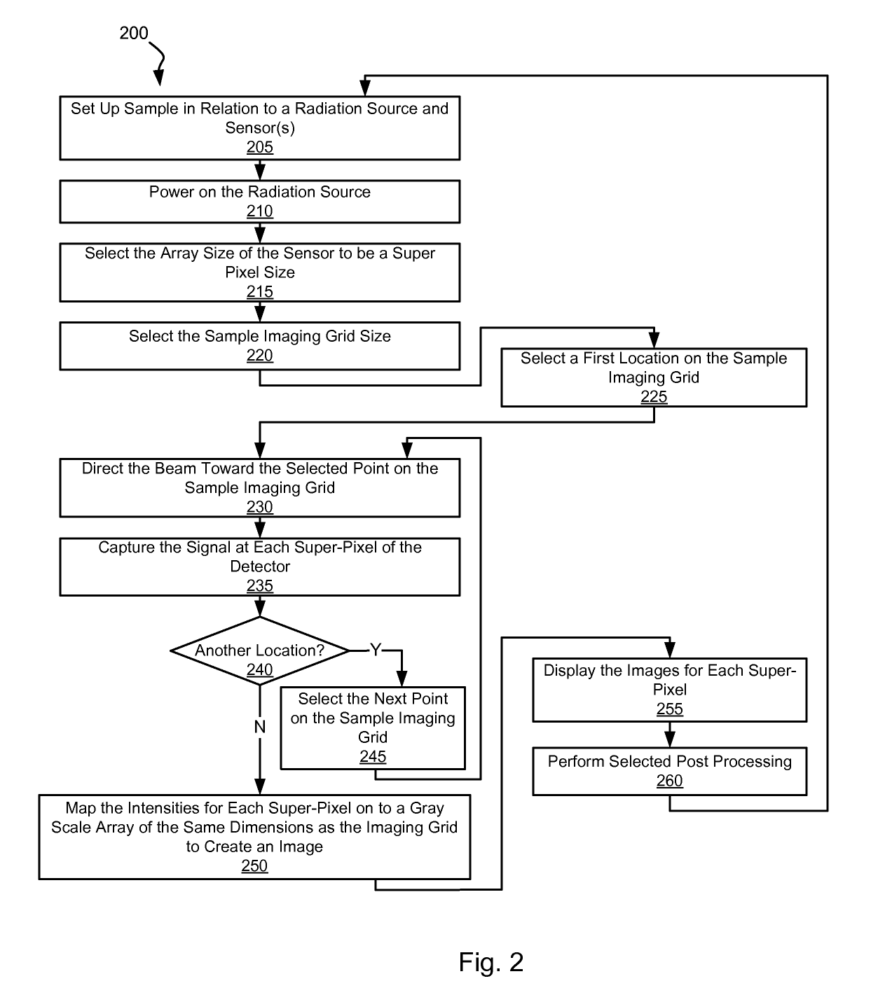

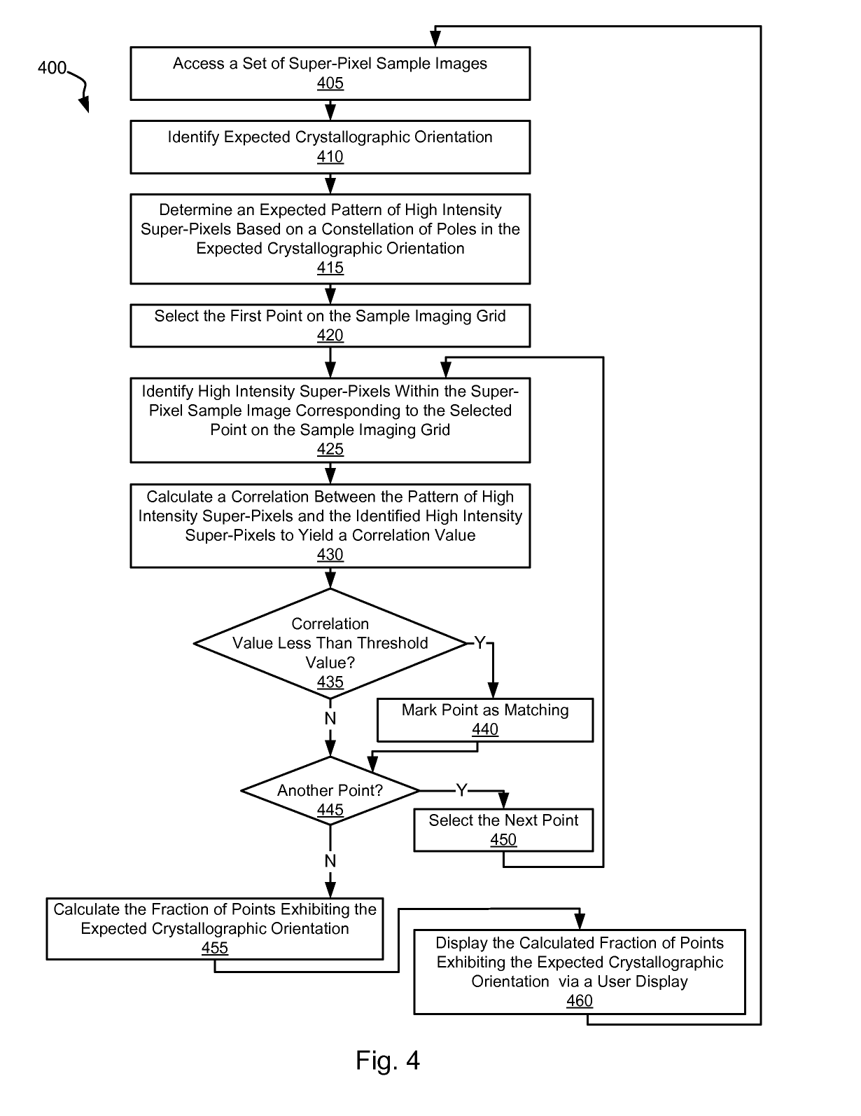

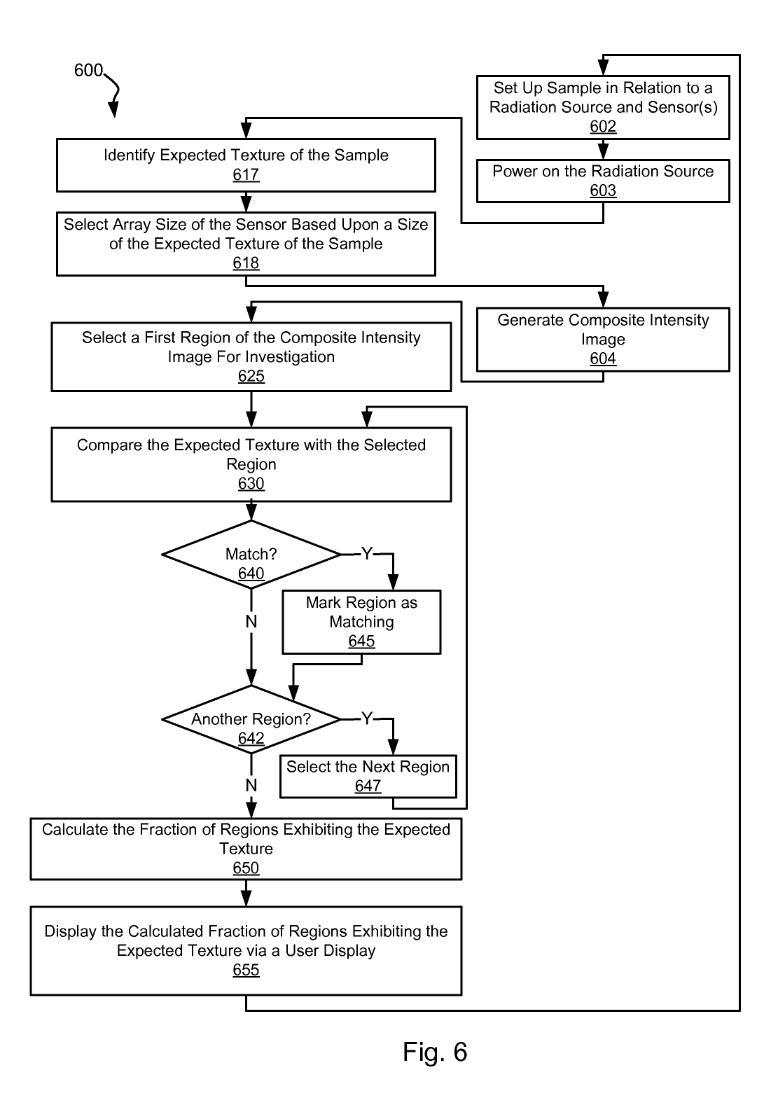

Data processor 176 accesses an instruction memory 180 that includes crystallographic texture measurement and smart scanning control 180. The word “texture” is generically used throughout this application to refer to “crystallographic texture”. In various embodiments of the present invention, the instructions are executable by a data processor 176 to perform the processes discussed below in relation to FIG. 2, FIG. 4, FIG. 6 and/or FIG. 7.

Material sample 140 may be any material known in the art. In some particular cases, material sample 140 is a crystalline or polycrystalline material. As an example, material sample 140 may be magnesium or some alloy thereof, or a single crystal silicon sample. As another example, material sample 140 may be a polymer. Based upon the disclosure provided herein, one of ordinary skill in the art will recognize a variety of materials that may be examined using embodiments of the present invention. Material sample 140 may be placed in a highly-tilted (e.g., approximately seventy degrees) orientation relative to electron beam 115.

Material investigation system 100 further includes an input device 150, a display 160, and a processing device 170. Input device 150 may be any input device known in the art that is capable of indicating a location on display 160. In one particular embodiment of the present invention, input device 150 is a mouse with a button 152. In one such case, location on display 160 is generated by moving mouse 150. Alternatively, a touch screen device may be used as input device 150. In such a case, the touch screen may designate location by touching a corresponding location on the touch screen. Based upon the disclosure provided herein, one of ordinary skill in the art will recognize a variety of input devices that may be used in relation to different embodiments of the present invention. Of note, detector 120, display 160, input device 150, and radiation source 110 may share the same processing device, use separate processing devices, or may use a combination of separate and shared processing devices. Further, each detector 120 may be associated with its own display or may share a common display.

Processing device 170 includes a beam aiming module 172, an input device controller 174, data processor 176 operable to execute instructions from instruction memory 180, an EBSD binning based image detection controller module 178, a detail image memory 180, an image memory 182, and a graphical user interface 184. In some embodiments of the present invention, processing device 170 is a general purpose computer executing processing instructions. In other embodiments of the present invention, processing device 170 is a circuit tailored to perform the operations of material investigation system 100. In yet other embodiments of the present invention, processing device 170 is a combination of a general purpose computer and circuitry tailored to perform the operations of material investigation system 100. Investigation controller module 178 is operable to control application of beam 115 and updates to display 160 through various phases of an investigation.

Beam aiming module 172 is operable to control the location to which radiation source 110 directs beam 115. Beam aiming module 172 relies on instructions from investigation controller module 178 and input device controller to properly direct beam 115. As an example, in one phase of using material investigation system 100, beam aiming module 172 directs radiation source 110 to scan across a defined grid of material sample 140. In a later phase, beam aiming module 172 directs radiation source 110 to a particular location or bin within the defined grid for a time period. The location and the time period are provided by input device controller 174 to beam aiming module 172.

Input device controller 174 is operable to generate control signals based upon one or more signals received from input device 150. As one example, input device controller 174 generates a time period based upon a length of time that button 152 is pressed, and a location based upon movement of input device 150. In some cases, the location is a fixed location. In other cases, the location is a number of positions along a path.

Image memory 182 is operable to store an image output corresponding to a map covering a defined region of material sample 140. The image output may include information relating to a number of grid locations distributed across the face of material sample 140. The stored guide image output may be developed by scanning beam 115 over a sample and sensing diffracted electron beam 117 by detector 120. In turn, detector 120 provides signal data 192 to data processor 176 that generates an image output corresponding to the surface of a defined region of material sample 140. This image output may be accessed by graphical user interface 184 where it is converted to a graphical representation of the defined region displayable by display 160.

The general idea is to reduce the number of pixels used in a sensor when imaging the surface of a sample, and thereby reduce the amount of processing required to investigate the surface of a sample. For example, the EBSD detector may provide an image array of 512×512 pixels which may be reduced through binning together blocks of pixels into a small array of super pixels (or bins)—such as but not limited to an array of 5×5 super pixels. As used herein the phrase “super pixel” is used in its broadest sense to mean any subset of an array of pixels available from a sensor. In one particular embodiment of the present invention, an image array of super pixels includes a five by five array of super pixels, where each super pixel is a composite of 100×100 pixels from the image array. The idea is that if we divide the 512×512 array into bins containing 100×100 pixels then we end up with essentially an image array containing only 5×5 super pixels.

Following flow diagram 200, a material sample is set up in relation to a radiation source and one or more sensors (block 205). This may include, for example, placing the sample material on a carrier apparatus such that radiation emitted from a radiation source is directed toward the surface of the sample material at a desired incidence angle. The radiation source is then turned on such that a beam emitted from the radiation source impacts the surface of the sample material (block 210). An array size of the sensor is selected to be the size of a super pixel (block 215). Said another way, the amount of binning applied to the detector is selected which determines the number of detector pixels within each super pixel. As such, the pixel dimensions of the image will be the same as the array of super pixels.

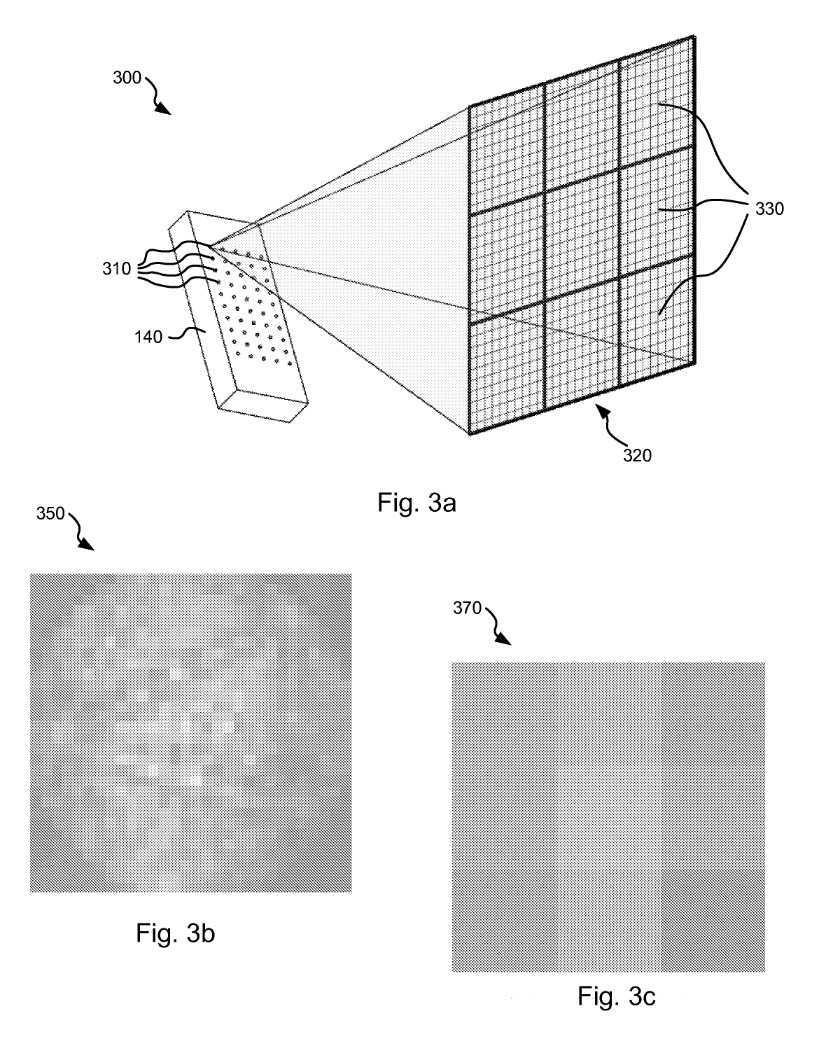

A sample imaging grid size is selected (block 220). For example, referring to FIG. 3a, material sample 140 is shown with the surface divided into a sample imaging grid with a number of grid points (examples labeled 310). FIG. 3a shows a composite image of a region of a material surface that may represent, for example, an electron backscatter diffraction pattern from a crystalline material sample. In a non-reduced approach, the selected grid point would be imaged using the full pixel array 320 which in this example is 30×30 which would yield an image 350 shown in FIG. 3b. In embodiments of the present invention, full pixel array 320 is divided into super pixels 330. In this example, the 30×30 pixel array is reduced to a 3×3 super pixel array (examples of the super pixels labeled 330) which would yield an image 370 of FIG. 3c.

A first location on the sample imaging grid is selected (block 225), and the beam is directed toward the selected location (block 230). With the beam directed at the selected location of the sample surface, the signal intensity collected from each super pixel is captured. The beam is then directed to a second location on the surface of the sample and once again the signal intensity recorded from each super pixel. This process is repeated for a set of locations forming a grid on the sample surface. Once the process is repeated an individual image can be formed of the sample surface for each super pixel. The image for a given super pixel is formed by mapping the intensity recorded in the super pixel at each grid location to a gray scale or to a color scale. (See e.g., FIG. 3c). As used herein, the term “capture” or “captured” are used in their broadest sense to mean sensing or detecting an input and recording a corresponding output at least temporarily. This essentially transforms the EBSD detector from a single detector for capturing individual EBSD patterns into a 3×3 array of individual backscatter imaging sensors. This image output of the selected bin includes data that is capable of processing to produce a graphical representation of the defined region. The individual values or elements of the interim output are scaled such that they cover a maximum value range for yield a binned intensity image output. Thus, for example, where the individual values of the interim output exhibit a maximum of x and a minimum of y, and a maximum supportable by an image output extends from x′ to y′, the scaling may be done in accordance with the following equation:

$$Binned Intensity Image Output ( i ) = Interim Output ( i ) [ \frac{{x}^{′} - {y}^{′}}{x - y} ] .$$

It is determined whether another location of the sample imaging grid remains to be processed (block 240). Where one or more locations remain for processing (block 240), the next location or point on the sample imaging grid is selected (block 245) and the processes of blocks 230-240 are repeated for the selected bin. Otherwise, where no additional locations of the sample imaging grid remain to be processed (block 240), the intensities for each of the super pixels on mapped to a gray scale array of the same overall dimensions as the imaging grid to create an overall image (block 250). The overall image including the information from each of the super pixels is displayed (block 255), and any selected post processing is performed (block 260). Such post processing may include, but is not limited to texture analysis.

Turning to FIG. 4, a flow diagram 400 shows a method in accordance with some embodiments of the present for performing texture analysis of a material sample in accordance with various embodiments of the present invention. A material is said to have texture if the constituent crystallites or grains have crystallographic orientations which are similar to one another. Thus to identify if a materials has a given crystallographic texture then the constituent grains must have crystallographic orientations near a specified orientation or specified range or orientations. Such texture analysis relies on orientation information that is generated as part of scanning the surface of a material sample. Information about the surface of the material may be derived from any image of the surface of the material including, for example, a composite image for each super pixel discussed in relation to FIG. 2 above.

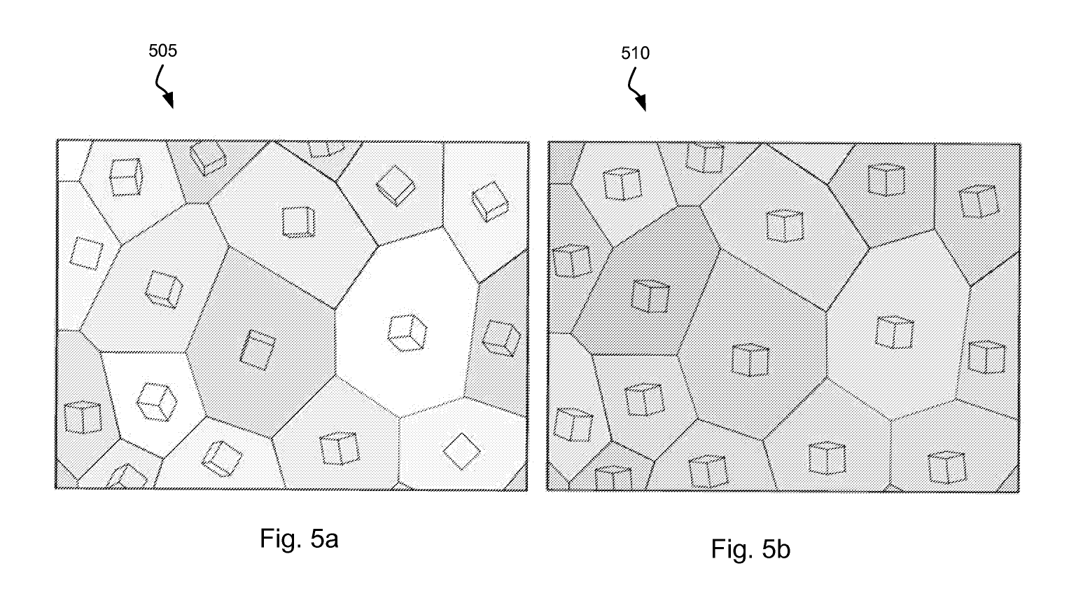

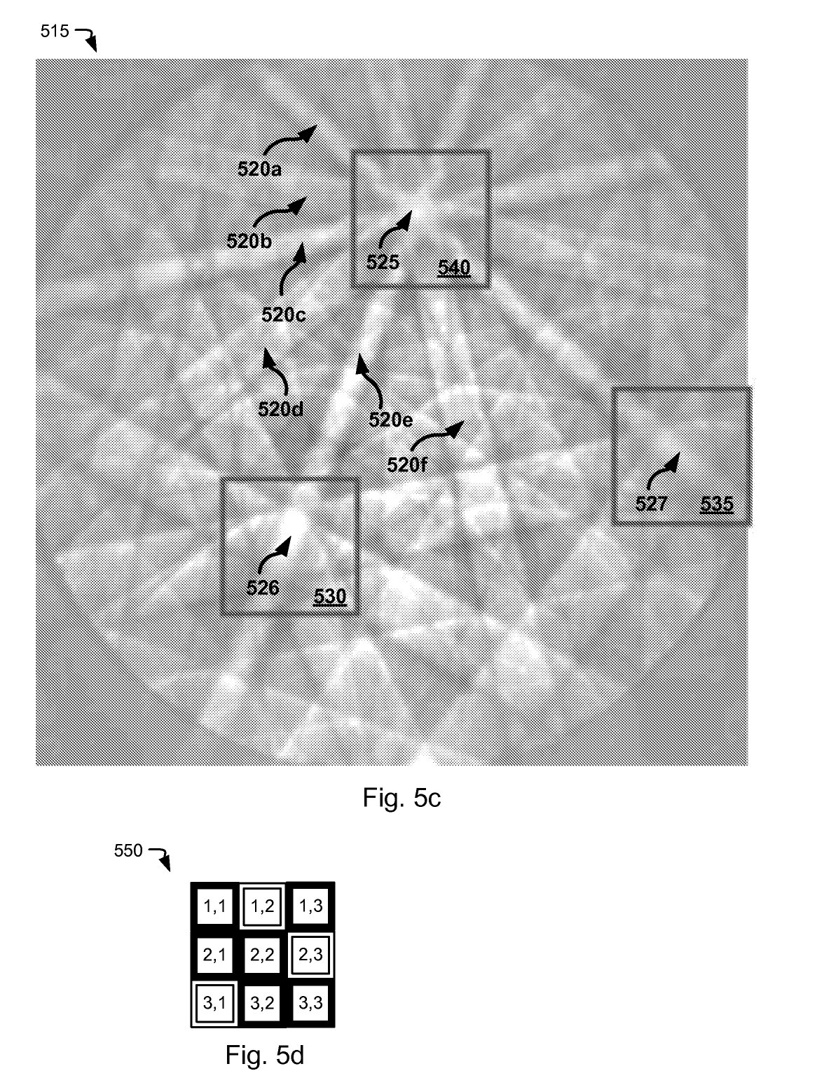

Following flow diagram 400, a set of super pixel images is accessed from memory (block 405). In some embodiments of the present invention, the set of super pixel images (e.g., a set of arrays of super pixels 330 corresponding to respective grid points 310) is derived from different locations across the surface of a sample. Using a simulation program it is possible for a user to identify an expected texture of the sample (block 410). This may include, for example, a user input that identifies a constellation of poles that should be found within a sample where the expected texture is occurring. For example, a pole may be expected at a first pixel location, and one or more poles are found at other pixel locations defined offsets from the first pixel location. Turning to FIGS. 5a-5b, a graphical representation 505 and a graphical representation 510 of images of the surface of a sample material is shown that includes a number of regions including grains represented as cubes in different orientations. Each of these grains exhibit a constellation of poles that correspond to the identified crystallographic orientation. In an intensity image, the intersection of bands at a pole generally appears brighter than other areas of the image. An example of these poles is shown in FIG. 5c. As shown in FIG. 5c, an example image 515 is shown that includes a number of bands 520a, 520b, 520c, 520d, 530e, 520f. The bands cross at poles 525, 526, 527 that occurred within the super pixels corresponding to locations 540, 530, 535, respectively. Locations 530, 535, 540 can be thought of as regions of interest or as apertures placed over the pattern. The expected texture or grain can be represented in a reference pattern as constellation of poles. This representation of the expected texture or grain may be either simulated or collected from a known sample material. An expected pattern of high intensity super pixels are determined based upon a constellation of poles for the expected crystallographic orientation (block 415). This process includes identifying super pixels in an array of super pixels are expected to exhibit a high intensity, and others that do not exhibit a high intensity. Using the example of FIG. 5c, the super pixels in the array of super pixels that exhibit a high intensity correspond to poles 525, 526, 527. Turning to FIG. 5d, an example of an expected texture 550 is shown as including a pole at a pixel location 2,2 outlined in white to indicate the relative brightness at a pole, a pole at a pixel location 3,1 again outlined in white to indicate the relative brightness at a pole, and a pole 2,3 again outlined in white to indicate the relative brightness at a pole. All of the other pixel locations (1,1; 1,3; 2,1; 2,2; 3,2; and 3,3) are outlined in black to indicate the relative obscurity at non-pole locations. Based upon the disclosure provided herein, one of ordinary skill in the art would recognize that another approach to the use of template based on a constellation of poles would be to create a template by simulating the pattern fully at the same pixel resolution as the super pixel array.

A first point of a sample imaging grid is selected (block 420). As an example, an array of super pixels 330 (i.e., a super pixel sample image) corresponding to one of the grid points 310 on sample 140 of FIG. 3a is selected. The super pixel sample image corresponding to the selected point of the imaging grid are inspected to identify which of the super pixels within the super pixel sample image exhibit a high intensity (i.e., an intensity greater than a user programmable threshold value). The expected pattern developed in block 415 is compared against the locations of the identified high intensity super pixels at the selected point in the sample imaging grid (block 430). This may include, for example, calculating a correlation between the selected point in the sample imaging grid and the expected pattern. This calculation may be, for example, a percentage of high intensity super pixels in the expected pattern that are matched in the super pixel sample image corresponding to the selected point. Based upon the disclosure provided herein, one of ordinary skill in the art will recognize other correlation calculations and/or approaches for determining a match that may be used in relation to different embodiments of the present invention. As a particular example relying on FIG. 5d, the constellation of poles results in pixels 1,2; 2,3 and 3,1 being bright in the highly binned image of the EBSD pattern. At a selected pixel in the 3×3 array of sample images corresponding to each of the 9 super pixels, then if the intensity is high in sample image 1,2; sample image 2,3 and sample image 3,1 then a match is declared for the sample grid point corresponding to the selected pixel in the sample images. Again, based upon the disclosure provided herein, one skilled in the art could imagine a variety of match metrics that can be used identify whether the intensities at the selected pixel in the super pixel images match those expected for the specified constellation of high intensity poles. This process is repeated for each super pixel in the super pixel sample image. The fraction of pixels declared a match is then easily determined. Based upon the disclosure provided herein, one of ordinary skill in the art will appreciate that the process of texture analysis may be done based upon a full pixel image, or upon a set of super pixel sampled images as part of a post processing procedure. Another approach would be to identify the set of the pixels in super pixel image 1,2 which are bright. Search through this set of pixel locations and remove from the set all those which are not bright in super pixel image 2,3. Further trim down the set by repeating the process for super pixel image 3.1.

It is determined whether a match was found (block 435). Where a similarity between the super pixel image and the expected pattern is represented as a correlation value, determining whether a match is found may include determining that the correlation value is less than a user programmable threshold value. Based upon the disclosure provided herein, one of ordinary skill in the art will recognize other approaches for determining that a match has been found. Where a match is found (block 435), the currently selected point of the sample imaging grid is marked as a match (block 440).

It is then determined whether another point on the sample imaging grid remains to be processed (block 445). Where another point remains to be processed (block 445), the next point on the sample imaging grid is selected (block 450) and the processes of blocks 425-445 are repeated for the newly selected point. Alternatively, where no other points remain to be processed (block 445), a fraction of the number of points that were marked as matching verses the overall number of points analyzed is calculated (block 455). The calculated fraction of points exhibiting the expected crystallographic orientation is displayed via a user display (block 460).

Turning to FIG. 6, a flow diagram 600 shows another method in accordance with other embodiments of the present for performing texture analysis of a material sample in accordance with various embodiments of the present invention. Such texture analysis relies on orientation information that is generated as part of scanning the surface of a material sample. Following flow diagram 600, a material sample is set up in relation to a radiation source and one or more sensors (block 602). This may include, for example, placing the sample material on a carrier apparatus such that radiation emitted from a radiation source is directed toward the surface of the sample material at a desired incidence angle. The radiation source is then turned on such that a beam emitted from the radiation source impacts the surface of the sample material (block 603).

An expected texture of the sample is identified (block 617). This may include, for example, a user input that identifies a constellation of poles that should be found within a sample where the expected texture is occurring. For example, a pole may be expected at a first pixel location, and one or more poles are found at other pixel locations defined offsets from the first pixel location. Turning to FIGS. 5a-5b, graphical representation 505 and graphical representation 510 of images of the surface of a sample material is shown that includes a number of regions including grains represented as cubes in different orientations. Each of these grains exhibit a constellation of poles that correspond to the particular grain. In an intensity image, the intersection of bands at a pole generally appears brighter than other areas of the image. An example of these poles is shown in FIG. 5c. As shown in FIG. 5c, example image 515 (in this case corresponding to a composite intensity image) is shown that includes a number of bands 520a, 520b, 520c, 520d, 530e, 520f. The bands cross at poles 525, 526, 527 that occurred at pixel locations 540, 530, 535, respectively. Pixel locations 530, 535, 540 can be thought of as regions of interest or as apertures placed over the pattern. The expected texture or grain can be represented in a reference pattern as a number of poles in relation to one another. This representation of the expected texture or grain may be either simulated or collected from a known sample material. Turning to FIG. 5d, an example of an expected texture 550 is shown as including a pole at a pixel location 2,2 outlined in white to indicate the relative brightness at a pole, a pole at a pixel location 3,1 again outlined in white to indicate the relative brightness at a pole, and a pole 2,3 again outlined in white to indicate the relative brightness at a pole. All of the other pixel locations (1,1; 1,3; 2,1; 2,2; 3,2; and 3,3) are outlined in black to indicate the relative obscurity at non-pole locations.

An array size of the sensor is selected to be an array of super-pixels (block 618). The number of pixels includes in each super-pixel and the number of super-pixels included in an overall image are selected as a balance between speed and accuracy. Increasing the number of pixels included in each super-pixel decreases the accuracy by aggregating a larger number of pixels together into a single value, but at the same time increases the speed at which texture processing may be completed due to the reduced number of values (i.e., values of the super-pixels) that are analyzed. In contrast, decreasing the number of pixels included in each super-pixel increases the accuracy by incorporating a smaller number of pixels together into a single value, but at the same time decreases the speed at which texture processing may be completed due to the increased number of values (i.e., values of the super-pixels) that are analyzed. With this selection, an image formed by the sensor will be the size of a super pixel. A composite intensity image is then generated (block 604). Generation of the composite intensity image may be done using the process set forth in blocks 225-260 of FIG. 2 that was discussed above.

A first region of the composite intensity image is selected (block 625). The selected region is of a size large enough to accommodate a constellation of poles corresponding to the expected texture. Thus, using FIG. 5d as an example where the constellation of poles can be represented as a 3×3 array of pixel locations, then the size of the selected region is selected as a square of nine pixel locations. Based upon the disclosure provided herein, one of ordinary skill in the art will recognize a variety of region sizes that may be used in relation to different embodiments of the present invention. The expected texture is compared with the selected region (block 630). Turning to FIG. 5e, an array of pixel locations 560 of the accessed composite intensity image is shown. Using array 560 as an example, the first selected region may include pixel locations 1,1; 1,2; 1,3; 2,1; 2,2; 2,3; 3,1; 3,2; 3,3. In this case, the location of the poles in the first region matches that of the expected texture.

It is determined whether a match was found (block 640). Where a match is found (block 640), the selected region is identified as matching. It is determined whether another of the composite intensity image remains to be investigated (block 642). Where another region remains to be investigated (block 642), the next region is selected (block 647) and the processes of blocks 640, 642, 645 are repeated for the next region. The next region may be selected, for example, by incrementing a column number until the last column in the composite intensity image is reached. Where the last column in the composite intensity image is reached, the column number is reset and the row number is incremented. This process of incrementing row and column numbers continues until all pixel locations have been investigated. As an example, referring to FIG. 5e, after pixel locations 1,1; 1,2; 1,3; 2,1; 2,2; 2,3; 3,1; 3,2; 3,3 have been processed, pixel locations 1,2; 1,3; 1,4; 2,2; 2,3; 2,4; 3,2; 3,3; 3,4 are processed and do not result in a match to the expected texture. The next match occurs when pixel locations 1,4; 1,5; 1,6; 2,4; 2,5; 2,6; 3,4; 3,5; 3,6 are processed and at that time these pixel locations are indicated as a match. Once the end of the columns has been reached (i.e., pixel locations 1,c-1; 1,c; 2,c-1; 2,c; 3,c-1; 3,c have been processed), pixel locations pixel locations 2,1; 2,2; 2,3; 3,1; 3,2; 3,3; 4,1; 4,2; 4,3 are processed.

Once all regions of the composite intensity image have been processed (block 640), a fraction of the intensity composite image exhibiting the expected texture is calculated (block 650). This includes calculating the number of pixel locations that were included in regions identified as matching the expected texture to yield a matching number, and dividing the matching number by the total number of pixel locations in the composite intensity image. This calculated fraction of regions exhibiting the expected texture is displayed via a user display (block 655).

In conclusion, the invention provides novel systems, devices, methods and arrangements for structure investigation. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A system for determining a crystallographic orientation of a material sample, the system comprising:
a detector system operable to generate an image corresponding to a location on a surface of a material sample;
a microprocessor operable to execute instructions to:
access a data set corresponding to the image;
using the data set to map locations in the image exhibiting an intensity greater than a threshold intensity to yield an image constellation;
compare the image constellation with an expected constellation to yield a match indication; and
identify the location on the surface of the material as having a crystallographic orientation corresponding to the expected constellation based upon the match indication.

2. The system of claim 1, wherein the microprocessor is further operable to execute instructions to:
receive pixel data from the detector circuit;
combine subsets of the pixel data to yield a set of super pixels, wherein the data set corresponding to the image includes the set of super pixels.

3. The system of claim 2, wherein each of the pixel data from the detector circuit is an intensity value corresponding to a sub-location within the image, and wherein each of the super pixels is a value corresponding to an average of intensity values for each of the pixel data from the detector circuit included in the subset of the pixel data corresponding to a respective one of the super pixels.

4. The system of claim 2, wherein the size of the subset of pixel data combined to yield a respective super pixel is user programmable.

5. The system of claim 2, wherein the image constellation is a map of the super pixels in the image that exceed the threshold intensity.

6. The system of claim 5, wherein the threshold intensity is user programmable.

7. The system of claim 2, wherein the location on a surface of the material sample is a first location on the surface of the material sample, wherein the image is a first image, wherein the data set corresponding to the image is a first data set corresponding to the first image, wherein the image constellation is a first image constellation, wherein the match indication is a first match indication, wherein the detector system is further operable to generate a second image corresponding to a second location on the surface of a material sample, and wherein the microprocessor is further operable to execute instructions to:
access a second data set corresponding to the second image;
using the second data set to map locations in the second image exhibiting an intensity greater than the threshold intensity to yield a second image constellation;
compare the second image constellation with the expected constellation to yield a second match indication; and
identify the second location on the surface of the material as having a crystallographic orientation corresponding to the expected constellation based upon the second match indication.

8. The system of claim 7, wherein the pixel data is a first pixel data, wherein the set of super pixels is a first set of super pixels, wherein the pixel data is a first pixel data, and wherein the microprocessor is further operable to execute instructions to:
receive a second pixel data from the detector circuit;
combine subsets of the second pixel data to yield a second set of super pixels, wherein the second data set corresponding to the second image includes the second set of super pixels.

9. The system of claim 7, wherein the microprocessor is further operable to execute instructions to:
calculate a fraction of locations on the surface of the material sample that match the expected constellation.

10. The system of claim 1, wherein the system further comprises:
a display system operable to display a graphical representation of the image corresponding to the location on a surface of the material sample.

11. The system of claim 1, wherein the detector system is selected from a group consisting of: a backscatter detector, a forward scatter detector, a secondary electron detector, and a combination of one or more of a backscatter detector, a forward scatter detector, and a secondary electron detector.

12. The system of claim 1, wherein the detector system is an electron back scatter diffraction detector.

13. A method for characterizing a material, the method comprising:
receiving an image corresponding to a location on a surface of a material sample;
accessing a data set corresponding to the image;
using the data set and a microprocessor to map locations in the image exhibiting an intensity greater than a threshold intensity to yield an image constellation;
comparing the image constellation with an expected constellation to yield a match indication; and
identifying the location on the surface of the material as having a crystallographic orientation corresponding to the expected constellation based upon the match indication.

14. The method of claim 13, wherein the image is an electron back scatter diffraction image.

15. The method of claim 13, wherein the method further comprises:
receiving pixel data from a detector circuit;
combining subsets of the pixel data to yield a set of super pixels, wherein the data set corresponding to the image includes the set of super pixels.

16. The system of claim 15, wherein each of the pixel data from the detector circuit is an intensity value corresponding to a sub-location within the image, and wherein each of the super pixels is a value corresponding to an average of intensity values for each of the pixel data from the detector circuit included in the subset of the pixel data corresponding to a respective one of the super pixels.

17. The method of claim 15, wherein the image constellation is a map of the super pixels in the image that exceed the threshold intensity.

18. The method of claim 15, wherein the location on a surface of the material sample is a first location on the surface of the material sample, wherein the image is a first image, wherein the data set corresponding to the image is a first data set corresponding to the first image, wherein the image constellation is a first image constellation, wherein the match indication is a first match indication, wherein the detector system is further operable to generate a second image corresponding to a second location on the surface of a material sample, and wherein the method further comprises:
accessing a second data set corresponding to the second image;
using the microprocessor and the second data set to map locations in the second image exhibiting an intensity greater than the threshold intensity to yield a second image constellation;
comparing the second image constellation with the expected constellation to yield a second match indication; and
identifying the second location on the surface of the material as having a crystallographic orientation corresponding to the expected constellation based upon the second match indication.

19. The method of claim 18, wherein the pixel data is a first pixel data, wherein the set of super pixels is a first set of super pixels, wherein the pixel data is a first pixel data, and wherein the method further comprises:
receiving a second pixel data from the detector circuit;
combining subsets of the second pixel data to yield a second set of super pixels, wherein the second data set corresponding to the second image includes the second set of super pixels.

20. The method of claim 13, wherein the method further comprises:
calculating a fraction of locations on the surface of the material sample that match the expected constellation.
